(19) United States
(12) Patent Application Publication
(10) Pub. No.: US 2014/0042122 A1
(43) Pub. Date: Feb. 13, 2014

(54) METHOD OF MANUFACTURING PRINTED CIRCUIT BOARD

(71) Applicant: SAMSUNG ELECTRO-MECHANICS CO., LTD., Suwon (KR)

(72) Inventors: Jae Mok Jung, Suwon (KR); Min Soo Kim, Suwon (KR); Hun June Song, Suwon (KR); Ba Wool Kim, Suwon (KR)

(73) Assignee: SAMSUNG ELECTRO-MECHANICS CO., LTD., Suwon (KR)

(21) Appl. No.: 13/963,907

(22) Filed: Aug. 9, 2013

(30) Foreign Application Priority Data
Aug. 13, 2012 (KR) 10-2012-0088449

(51) Int. Cl. H05K 3/00; H05K 3/10

(52) U.S. Cl. CPC H05K 3/0079; H05K 3/0041; H05K 3/107
USPC 216/18

(57) ABSTRACT

Disclosed herein is a method of manufacturing a printed circuit board, the method including: preparing a base substrate having an insulating layer and a connection pad formed in the insulating layer; forming a photosensitive resist on the insulating layer; forming an opening part of which a side surface has a foot shape by patterning the photosensitive resist; forming a via hole exposing the connection pad by etching the insulating layer exposed by the opening part; and forming a via by filling the via hole.

### CROSS REFERENCE TO RELATED APPLICATION

This application claims the benefit of Korean Patent Application No. 10-2012-0088449, filed on Aug. 13, 2012, entitled “Method of Manufacturing a Printed Circuit Board”, which is hereby incorporated by reference in its entirety into this application.

### BACKGROUND OF THE INVENTION

1. Technical Field

The present invention relates to a method of manufacturing a printed circuit board.

2. Description of the Related Art

Recently, a demand for a technology of directly mounting a semiconductor chip on a printed circuit board with high density of the semiconductor chip, and high speed of signal transmission speed has become increased. Accordingly, a printed circuit board having high density and high reliability capable of implementing a high density semiconductor chip has been required to be developed.

Specification which is required for the printed circuit board having the high density and high reliability has a close relationship with that of the semiconductor chip, and there are many challenges such as miniaturization of a circuit, high electrical property, high speed signal transmission structure, high reliability, high functionality, and the like. In order to implement these challenges, a technology of a printed circuit board capable of forming a via hole is required. U.S. Pat. No. 6,240,636 discloses the via hole formed by generally using a laser or a drill. However, in the case of forming the via hole by using the laser or the drill, a plurality of via holes are required to be individually processed. In the case of forming the via hole by using plasma, the plurality of via holes may be simultaneously processed. However, at the time of performing a plasma etching process, the via hole is orthogonally etched due to a straight property of the plasma. In the case in which the via hole does not have a tapered shape but is orthogonally etched, at the time of filling the via hole by an electroplating process, a void may be generated therein.

### SUMMARY OF THE INVENTION

The present invention has been made in an effort to provide a method of manufacturing a printed circuit board capable of forming a via hole having a tapered shape by a plasma etching method by forming an opening part of a photosensitive resist in a foot shape.

Further, the present invention has been made in an effort to provide a method of to manufacturing a printed circuit board capable of simultaneously forming a plurality of via holes by a plasma etching method.

According to a preferred embodiment of the present invention, there is provided a method of manufacturing a printed circuit board, the method including: preparing a base substrate having an insulating layer and a connection pad formed in the insulating layer; forming a photosensitive resist on the insulating layer; forming an opening part of which a side surface has a foot shape by patterning the photosensitive resist; forming a via hole exposing the connection pad by etching the insulating layer exposed by the opening part; and forming a via by filling the via hole.

The photosensitive resist may be made of a positive photosensitive material.

The forming of the opening part of which the side surface has the foot shape may include: forming a mask on the photosensitive resist for patterning the opening part; exposing the photosensitive resist; removing the mask; and forming the opening part by developing the photosensitive resist.

In the forming of the mask, the mask may be patterned so that an upper portion of a region in which the opening part of the photosensitive resist is to be formed is closed.

In the forming of the opening part, the foot of the opening part may be controlled by an exposure amount at the time of exposing the photosensitive resist.

In the forming of the opening part, the foot of the opening part may be formed by performing a development process under an overdevelopment condition or an underdevelopment condition.

In the forming of the opening part, the foot of the opening part may be controlled by a thickness of the photosensitive resist.

The method may further include, before the exposing of the photosensitive resist, curing the photosensitive resist.

The photosensitive resist may be made of a negative photosensitive material.

The forming of the opening part of which a side surface has a foot shape may include: forming a mask on the photosensitive resist for patterning of the opening part; exposing the to photosensitive resist; removing the mask; and forming the opening part by developing the photosensitive resist.

In the forming of the mask, the mask may be patterned so that an upper portion of a region in which the opening part of the photosensitive resist is to be formed is open.

In the forming of the opening part, the foot of the opening part may be controlled by an exposure amount at the time of exposing the photosensitive resist.

In the forming of the opening part, the foot of the opening part may be formed by performing a development process under an overdevelopment condition or an underdevelopment condition.

In the forming of the opening part, the foot of the opening part may be controlled by a thickness of the photosensitive resist.

In the forming of the via hole, the via hole may be formed by a plasma etching method.

The method may further include, after the forming of the via hole, removing the photosensitive resist remaining on the insulating layer.

In the forming of the photosensitive resist, the photosensitive resist may be coated in a liquid state.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 9 are exemplary views showing a method of manufacturing a printed circuit board according to the preferred embodiment of the present invention; and

FIGS. 10 to 18 are exemplary views showing a method of manufacturing a printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

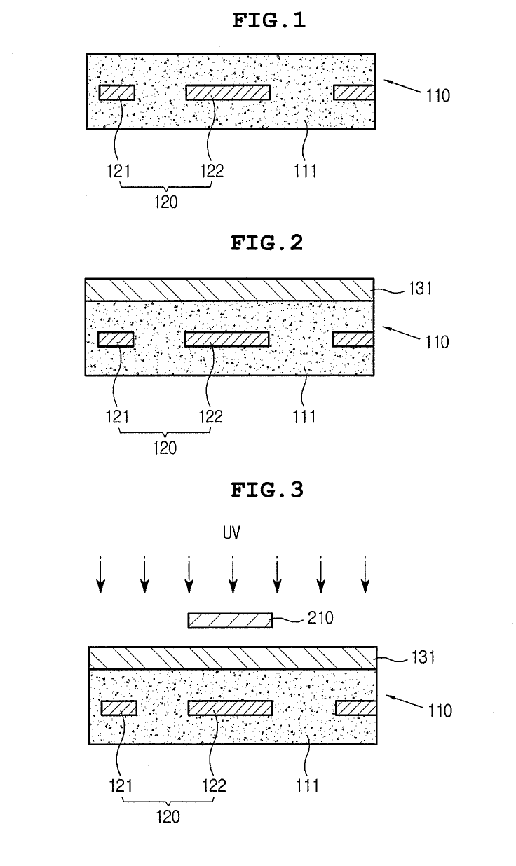

FIGS. 1 to 9 are exemplary views showing a method of manufacturing a printed circuit board according to a preferred embodiment of the present invention.

Referring to FIG. 1, a base substrate 110 is prepared. The base substrate 110 may include an insulating layer 111 and a circuit layer 120.

The insulating layer 111 may be made of a composite polymer resin that is generally used as an interlayer insulation material. For example, the insulating layer 111 may be made of a prepreg, or an epoxy based resin such as Ajinomoto Build up Film (ABF), FR-4, a Bismaleimide Triazine (BT) or the like. In addition, the insulating layer may have a form of a substrate or a film. However, the material and the form of the insulating layer are not limited in the preferred embodiment of the present invention.

The circuit layer 120 may include a circuit pattern 121, a connection pad 122, and a via (not shown). The circuit layer 120 may be made of a conductive material. For example, the conductive material may be an electrically conductive metal such as gold, silver, zinc, nickel, copper, or the like.

The circuit layer 120 may be formed in the insulating layer 111. In FIG. 1, the circuit layer 120 formed in the insulating layer 111 is shown as a single layer, but is not limited thereto. That is, the circuit layer 120 may be formed in a single layer and a multilayer.

Referring to FIG. 2, a photosensitive resist 131 may be formed on the base substrate 110. The photosensitive resist 131 may be formed on the insulating layer 111 of the base substrate 110. The photosensitive resist 131 may be made of a positive photosensitive material in the preferred embodiment of the present invention. In addition, the photosensitive resist 132 may be formed by being coated in a liquid state on the insulating layer 111. The photosensitive resist 131 may be formed so as to have a thickness enough to form a foot in the opening part 140 to be formed later. That is, a shape of the foot of the opening part 140 to be formed later may be controlled according to the thickness of the photosensitive resist 131. For example, the photosensitive resist 131 may have a thickness of 10 um to 150 um, which is a general range in the industry. However, in the case in which the thickness of the photosensitive resist 131 is deviated from the above-mentioned range, at the time of forming the opening part 140, the photosensitive resist 131 may have the thickness of several nm to several mm in which the foot may be formed.

Referring to FIG. 3, a mask 210 may be formed on the photosensitive resist 131. The mask 210 may be formed in an upper portion of a region in which the opening part 140 of the photosensitive resist 131 is to be formed. The mask 210 may be formed in a shape in which a portion corresponding to a region in which the opening part 140 of the photosensitive resist 131 is formed is closed. That is, the mask 210 may be formed so that other regions except a region in which the opening part 140 of the photosensitive resist 131 are exposed to the outside.

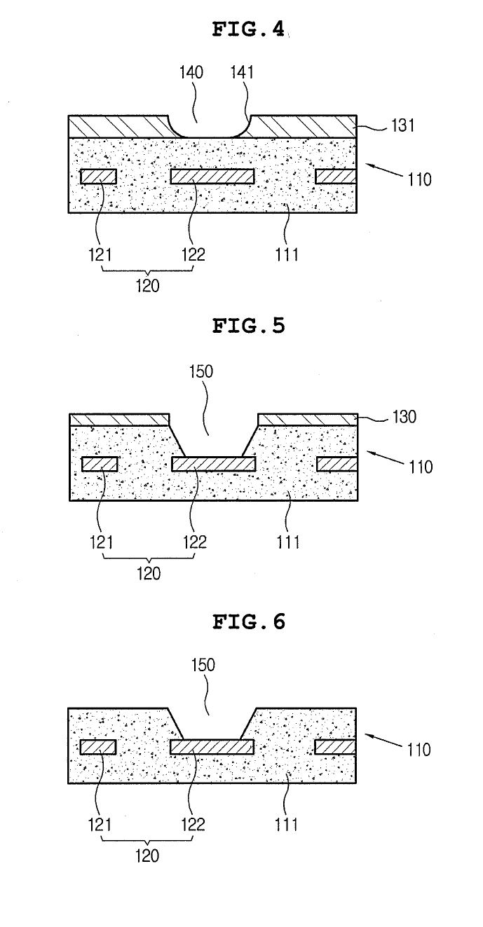

Referring to FIG. 4, the opening part 140 may be formed in the photosensitive resist 131. The opening part 140 of the photosensitive resist 131 may be formed so as to expose the insulating layer 111 positioned on the connection pad 122.

The opening part 140 may be formed by performing exposure and development processes on the photosensitive resist 131. Firstly, a thermosetting process may be performed on the photosensitive resist 131.

After performing the thermosetting process, the exposure process may be performed on the photosensitive resist 131. Here, the exposure process may be performed on the remaining region of the photosensitive resist 131 except the region which is closed by the mask 210. Here, an exposure amount is controlled, thereby making it possible to form the opening part 140 in a foot shape later. For example, the exposure process may be performed with the exposure amount in which the singular number of steps has the range of ±20% to 250%. However, at the time of performing the exposure process, the exposure amount is not limited thereto. In the case in which the foot of the opening part 140 may be controlled, the exposure process may be performed in the range at which the singular number of steps is ±1% to 500%.

After performing the exposure process, the mask 210 formed on the photosensitive resist 131 may be removed.

After removing the mask 210, the development process may be performed on the photosensitive resist 131. In the photosensitive resist 131, a portion at which the exposure process is not performed may be removed by a developer. That is, the region of the photosensitive resist 131 closed by the mask 210 is removed, thereby making it possible to form the opening part 140. Here, the development process is performed under an overdevelopment condition or an underdevelopment condition, thereby making it possible to form the foot of the opening part 140.

By performing the thermosetting, exposure, and development processes, the opening part 140 of which the side surface 141 has a foot shape may be formed in the photosensitive resist 131.

In the preferred embodiment of the present invention, the thermosetting process is performed before the exposure process in order to form the opening part 140 of which the side surface 141 has the foot shape, but is not limited thereto. The thermosetting process may be easily omitted by those skilled in the art, according to a material, or the like, of the photosensitive resist 131.

In addition, in the preferred embodiment of the present invention, both of the exposure and the development processes are performed according to each condition in order to form the foot of the opening part 140, but is not limited thereto. That is, only one condition of the exposure condition and the development condition for forming the foot of the opening part 140 is selected to perform the exposure and the development processes, thereby making it possible to form the opening part 140 having the foot shape.

Referring to FIG. 5, a via hole 150 may be formed on the base substrate 110. The via hole 150 may be formed by etching the insulating layer 111 exposed by the opening part 140 of the photosensitive resist 131. The via hole 150 may be formed by a plasma etching method. In the plasma etching method, a plurality of via holes 150 may be simultaneously formed. The plasma etching process may be performed until the connection pad 122 is exposed to the outside.

Here, at the time of performing the plasma etching process, the via hole 150 may be formed in a tapered shape by the opening part 140 having the foot shape of the photosensitive resist 131. In the opening part 140 having the foot shape in which the side surface 141 thereof has a slope, an upper diameter and a bottom diameter of the opening part 140 are different, respectively. That is, in the side surface 141 of the opening part 140, height thereof may be smaller toward the center of the opening part 140. Therefore, a thickness of the photosensitive resist 131 may be smaller toward the center of the opening part 140. At the time of the plasma etching process, the insulating layer 111 may be etched in proportion to the thickness of the photosensitive resist 131. That is, in a region having a thick thickness of the photosensitive resist 131, the insulating layer 11 may be thinly etched, in a region having a thin thickness of the photosensitive resist 131, the insulating layer 111 may be deeply etched, and in a region not having the photosensitive resist 131, the insulating layer 111 may be etched at maximum.

As described above, the opening part 140 of the photosensitive resist 131 has the foot shape, such that the via hole 150 may be formed in the tapered shape even in the case in which the etching process is performed by the plasma having a straight property.

Due to the properties of plasma etching, at the time of etching the insulating layer 111, the photosensitive resist 131 exposed to the plasma may be also simultaneously etched. Therefore, as shown in FIG. 5, as the via hole 150 is formed, the photosensitive resist 131 may be removed, or the thickness thereof may be reduced.

Referring to FIG. 6, the photosensitive resist 131 remaining on the base substrate 110 may be removed. The photosensitive resist 131 may be removed by the plasma etching process performed for forming the via hole 150. However, in the case in which the thickness of the photosensitive resist 131 is thick, the photosensitive resist 131 may remain on the base substrate 110 even after forming the via hole 150. In order to remove the photosensitive resist 131 remaining on the base substrate 110, a desmear process may be performed.

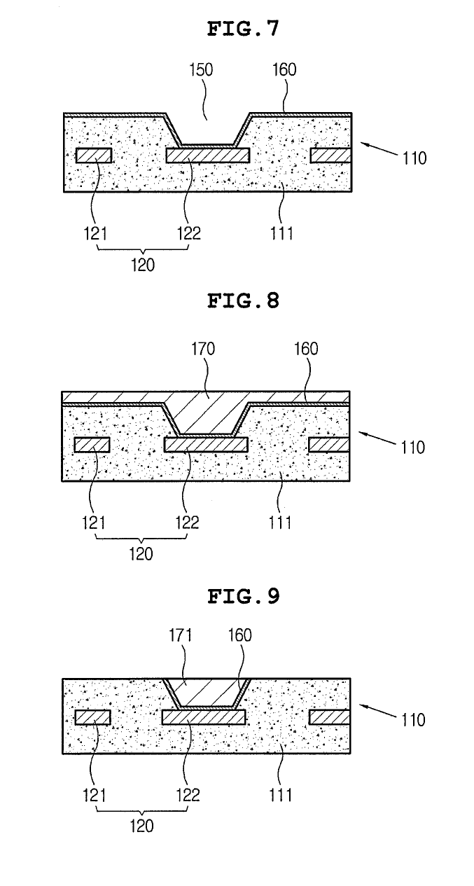

Referring to FIG. 7, a seed layer 160 may be formed on the insulating layer 111 and inner wall of the via hole 150. The seed layer 160 may be formed so as to serve as a leadline for an electroplating process to be performed later. For example, a method of forming the seed layer 160 is not specifically limited, but conventional depositing methods known in the art may be used. For example, the seed layer 160 may be formed by a wet plating method such as an electroless plating method. Otherwise, the seed layer 160 may be formed by a dry plating method such as a sputtering method.

Referring to FIG. 8, a metal layer 170 may be formed on the seed layer 160 and inner wall of the via hole 150. The metal layer 170 may be made of a conductive material. For example, the conductive material may be an electrically conductive metal such as gold, silver, zinc, nickel, copper, or the like. A method of forming the metal layer 170 is not specifically limited, but conventional depositing methods known in the art may be used. For example, the metal layer 170 may be formed by using the seed layer 160 as the leadline and performing the electroplating process.

Referring to FIG. 9, a via 171 may be formed. The via 171 may be formed by removing the remaining metal layer 170 and the seed layer 160 except the metal layer 170 filled in the via hole 150. For example, the metal layer 170 and the seed layer 160 may be removed by a physical polishing machining process. Otherwise, the metal layer 170 and the seed layer 160 may be removed by a city etching process and a wet etching process. In FIG. 9, only the via 171 is formed, but is not limited thereto. That is, in addition to the via 171, a circuit pattern may be formed on the insulating layer 111 by patterning the metal layer 170.

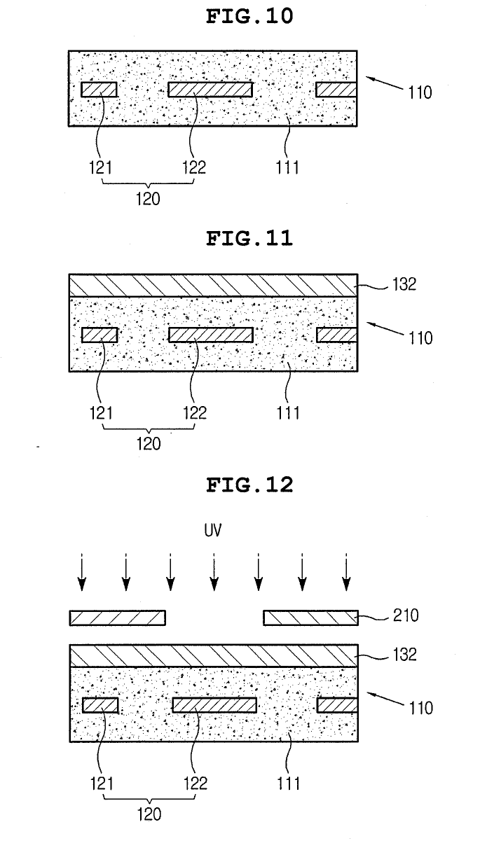

FIGS. 10 to 18 are exemplary views showing a method of manufacturing a printed circuit board according to another preferred embodiment of the present invention. Referring to FIG. 10, the base substrate 110 is prepared. The base substrate 110 may include an insulating layer 111 and a circuit layer 120.

The insulating layer 111 may be made of a composite polymer resin that is generally used as an interlayer insulation material. For example, the insulating layer 111 may be made of a prepreg, or an epoxy based resin such as Ajinomoto Build up Film (ABF), FR-4, a Bismaleimide Triazine (131) or the like. In addition, the insulating layer may have a form of a substrate or a film.

However, the material and the form of the insulating layer are not limited in the preferred embodiment of the present invention.

The circuit layer 120 may include a circuit pattern 121, a connection pad 122, and a via (not shown). The circuit layer 120 may be made of a conductive material. For example, the conductive material may be an electrically conductive metal such as gold, silver, zinc, nickel, copper, or the like.

The circuit layer 120 may be formed in the insulating layer 111. In FIG. 1, the circuit layer 120 formed in the insulating layer 111 is shown as a single layer, but is not limited thereto. That is, the circuit layer 120 may be formed in a single layer and a multilayer.

Referring to FIG. 11, a photosensitive resist 132 may be formed on the base substrate 110. The photosensitive resist 132 may be formed on the insulating layer 111 of the base substrate 110. The photosensitive resist 132 may be made of a negative photosensitive material in another preferred embodiment of the present invention. In addition, the photosensitive resist 132 may be formed by being coated in a liquid state on the insulating layer 111. The photosensitive resist 132 may be formed so as to have a thickness enough to form a foot in the opening part 140 to be formed later. That is, a shape of the foot of the opening part 140 to be formed later may be controlled according to the thickness of the photosensitive resist 132. For example, the photosensitive resist 132 may have a thickness of 10 um to 150 um, which is a general range in the industry. However, in the case in which the thickness of the photosensitive resist 132 is deviated from the above-mentioned range, at the time of forming the opening part 140, the photosensitive resist 132 may have the thickness of several nm to several mm in which the foot may be formed.

Referring to FIG. 12, a mask 210 may be formed on the photosensitive resist 132. The mask 210 may be formed in a shape in which a portion corresponding to a region in which the opening part 140 of the photosensitive resist 132 is formed is open. That is, the mask 210 may be formed so as to expose only the region in which the opening part 140 is to be formed in the photosensitive resist 132 to the outside.

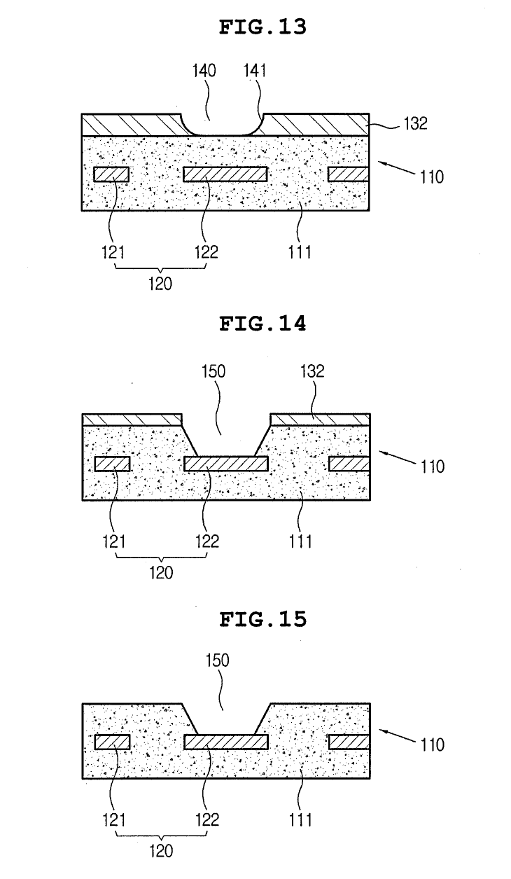

Referring to FIG. 13, the mask 140 may be formed on the photosensitive resist 132. The opening part 140 of the photosensitive resist 132 may be formed so as to expose the insulating layer 111 positioned on the connection pad 122.

The opening part 140 may be formed by performing exposure and development processes on the photosensitive resist 132.

Firstly, the exposure process may be performed on the photosensitive resist 132. Here, the exposure process may be performed only in the region open by the mask 210. Here, an exposure amount is controlled, thereby making it possible to form the opening part 140 in a foot shape later. For example, the exposure process may be performed with the exposure amount in which the singular number of steps is ±20% to 250%. However, at the time of performing the exposure process, the exposure amount is not limited thereto. In the case in which the foot of the opening part 140 may be controlled, the exposure process may be performed in the range at which the singular number of steps is ±1% to 500%.

After performing the exposure process, the mask 210 formed on the photosensitive resist 132 may be removed.

After removing the mask 210, the development process may be performed on the photosensitive resist 132. In the photosensitive resist 132, a portion at which the exposure process is performed may be removed by a developer. Here, the development process is performed under an overdevelopment condition or an underdevelopment condition, thereby making it possible to form the foot of the opening part 140.

By performing the exposure and the development processes, the opening part 140 of which the side surface 141 has a foot shape may be formed in the photosensitive resist 132.

In the preferred embodiment of the present invention, both of the exposure and the development processes are performed according to each condition in order to form the foot of the opening part 140, but is not limited thereto. That is, only one condition of the exposure condition and the development condition for forming the foot of the opening part 140 is selected to perform the exposure and the development processes, thereby making it possible to form the opening part 140 having the foot shape.

Referring to FIG. 14, a via hole 150 may be formed on the base substrate 110. The via hole 150 may be formed by etching the insulating layer 111 exposed by the opening part 140 of the photosensitive resist 132. The via hole 150 may be formed by a plasma etching method. The plasma etching may be performed until the connection pad 122 is exposed to the outside.

Here, at the time of performing the plasma etching process, the via hole 150 may be formed in a tapered shape by the opening part 140 having the foot shape of the photosensitive resist 132. In the opening part 140 having the foot shape in which the side surface 141 thereof has a slope, an upper diameter and a bottom diameter of the opening part 140 are different, respectively. That is, in the side surface 141 of the opening part 140, height thereof may be smaller toward the center of the opening part 140. Therefore, a thickness of the photosensitive resist 132 may be smaller toward the center of the opening part 140. At the time of the plasma etching process, the insulating layer 111 may be etched in proportion to the thickness of the photosensitive resist 132. That is, in a region having a thick thickness of the photosensitive resist 132, the insulating layer 11 may be thinly etched, in a region having a thin thickness of the photosensitive resist 132, the insulating layer 111 may be deeply etched, and in a region not having the photosensitive resist 132, the insulating layer 111 may be etched as much as possible.

As described above, the opening part 140 of the photosensitive resist 132 has the foot shape, such that the via hole 150 may be formed in the tapered shape even in the case in which the etching process is performed by the plasma having a straight property.

Due to the properties of the plasma etching, at the time of etching the insulating layer 111, the photosensitive resist 132 exposed to the plasma may be also simultaneously etched. Therefore, as shown in FIG. 14, as the via hole 150 is formed, the photosensitive resist 132 may be removed, or the thickness thereof may be reduced.

Referring to FIG. 15, the photosensitive resist 132 remaining on the base substrate 110 may be removed. The photosensitive resist 132 may be removed by the plasma etching process performed for forming the via hole 150. However, in the case in which the thickness of the photosensitive resist 132 is thick, the photosensitive resist 132 may remain on the base substrate 110 even after forming the via hole 150. In order to remove the photosensitive resist 132 remaining on the base substrate 110, a desmear process may be performed.

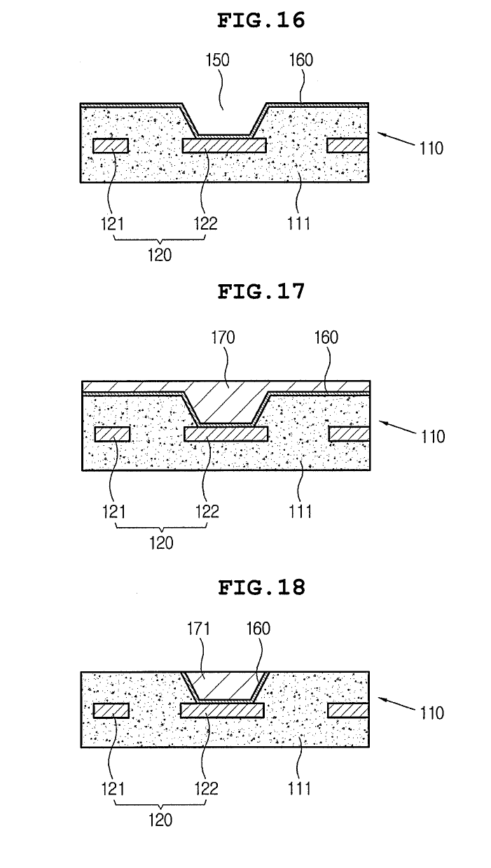

Referring to FIG. 16, a seed layer 150 may be formed on the insulating layer 111 and inner wall of the via hole 150. The seed layer 160 may be formed so as to serve as a leadline for an electroplating process to be performed later. For example, a method of forming the seed layer 160 is not specifically limited, but conventional depositing methods known in the art may be used. For example, the seed layer 160 may be formed by a wet plating method such as an electroless plating method. Otherwise, the seed layer 160 may be formed by a dry plating method such as a sputtering method.

Referring to FIG. 17, a metal layer 170 may be formed on the seed layer 160 and inner wall of the via hole 150. The metal layer 170 may be made of a conductive material. For example, the conductive material may be an electrically conductive metal such as gold, silver, zinc, nickel, copper, or the like. A method of forming the metal layer 170 is not specifically limited, but conventional depositing methods known in the art may be used. For example, the metal layer 170 may be formed by using the seed layer 160 as the leadline and performing the electroplating process.

Referring to FIG. 18, a via 171 may be formed. The via 171 may be formed by removing the remaining metal layer 170 and the seed layer 160 except the metal layer 170 filled in the via hole 150. For example, the metal layer 170 and the seed layer 160 may be removed by a physical polishing process. Otherwise, the metal layer 170 and the seed layer 160 may be removed by a dry etching process and a wet etching process. In FIG. 9, only the via 171 is formed, but is not limited thereto. That is, in addition to the via 171, a circuit pattern may be formed on the insulating layer 111 by patterning the metal layer 170.

As set forth above, with the method of manufacturing the printed circuit board according to the preferred embodiment of the present invention, the opening part of the photosensitive resist is formed in the foot shape, thereby making it possible to form the via hole having the tapered shape using the plasma etching method.

In addition, with the method of manufacturing the printed circuit board according to the preferred embodiment of the present invention, the via hole is formed by the plasma etching method, thereby making it possible to simultaneously form the plurality of via holes.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A method of manufacturing a printed circuit board, the method comprising:
preparing a base substrate having an insulating layer and a connection pad formed in the insulating layer;
forming a photosensitive resist on the insulating layer;
forming an opening part of which a side surface has a foot shape by patterning the photosensitive resist;
forming a via hole exposing the connection pad by etching the insulating layer exposed by the opening part; and
forming a via by filling the via hole.

2. The method as set forth in claim 1, wherein the photosensitive resist is made of a positive photosensitive material.

3. The method as set forth in claim 2, wherein the forming of the opening part of which the side surface has the foot shape includes:
forming a mask on the photosensitive resist for patterning the opening part;
exposing the photosensitive resist;
removing the mask; and
forming the opening part by developing the photosensitive resist.

4. The method as set forth in claim 3, wherein in the forming of the mask, the mask is patterned so that an upper portion of a region in which the opening part of the photosensitive resist is to be formed is closed.

5. The method as set forth in claim 3, wherein in the forming of the opening part, the foot of the opening part is controlled by an exposure amount at the time of exposing the photosensitive resist.

6. The method as set forth in claim 3, wherein in the forming of the opening part, the foot of the opening part is formed by performing a development process under an overdevelopment condition or an underdevelopment condition.

7. The method as set forth in claim 3, wherein in the forming of the opening part, the foot of the opening part is controlled by a thickness of the photosensitive resist.

8. The method as set forth in claim 3, further comprising, before the exposing of the photosensitive resist, curing the photosensitive resist.

9. The method as set forth in claim 1, wherein the photosensitive resist is made of a negative photosensitive material.

10. The method as set forth in claim 9, wherein the forming of the opening part of which a side surface has a foot shape includes:
forming a mask on the photosensitive resist for patterning of the opening part;
exposing the photosensitive resist;
removing the mask; and
forming the opening part by developing the photosensitive resist.

11. The method as set forth in claim 10, wherein in the forming of the mask, the mask is patterned so that an upper portion of a region in which the opening part of the photosensitive resist is to be formed is open.

12. The method as set forth in claim 10, wherein in the forming of the opening part, the foot of the opening part is controlled by an exposure amount at the time of exposing the photosensitive resist

13. The method as set forth in claim 10, wherein in the forming of the opening part, the foot of the opening part is formed by performing a development process under an overdevelopment condition or an underdevelopment condition.

14. The method as set forth in claim 10, wherein in the forming of the opening part, the foot of the opening part is controlled by a thickness of the photosensitive resist.

15. The method as set forth in claim 1, wherein in the forming of the via hole, the via hole is formed by a plasma etching method.

16. The method as set forth in claim 1, further comprising, after the forming of the via hole, removing the photosensitive resist remaining on the insulating layer.

17. The method as set forth in claim 1, wherein in the forming of the photosensitive resist, the photosensitive resist is coated in a liquid state.
